(19) United States
(12) Patent Application Publication
(10) Pub. No.: US 2010/0200914 A1
(43) Pub. Date: Aug. 12, 2010

(54) SEMICONDUCTOR DEVICE AND METHOD OF MANUFACTURING THE SAME

(75) Inventor: Mitsuhiro Hamada, Niigata (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/702,744

(22) Filed: Feb. 9, 2010

(30) Foreign Application Priority Data
Feb. 10, 2009 (JP) 2009-027952

(51) Int. Cl. H01L 29/78; H01L 21/28

(52) U.S. Cl. 257/330; 438/510; 438/270; 257/E21.158; 257/E29.262

(57) ABSTRACT

A source layer 13 is so high that the source layer 13 and a source electrode 20 can be connected to each other mainly by the sides of the source layer 13. Thus, the width of the source layer 13 can be minimized and size reduction can be achieved. At the same time, insulating films 19 with a sufficient thickness can be formed in trenches 15 and thus the insulating films 19 are not formed on the source layer 13. Thus it is possible to deeply form a recessed structure 17 while suppressing unevenness on the source electrode 20, thereby improving a breakdown voltage.

### FIELD OF THE INVENTION

The present invention relates to a semiconductor device and particularly relates to a vertical MOSFET with a high withstand voltage and a method of manufacturing the same.

### BACKGROUND OF THE INVENTION

In vertical MOSFETs used for the switches and the like of power supplies, it has been required to improve a breakdown voltage while reducing an on resistance. In a vertical MOSFET with a high withstand voltage according to the prior art, a breakdown voltage has been improved by stabilizing the potential of a channel region while increasing the impurity concentrations of a body contact electrode and a well layer and reducing the parasitic resistances of the body contact electrode and the well layer.

Referring to FIG. 6, the following will describe the structure of a vertical MOSFET with a high withstand voltage according to the prior art.

FIG. 6 is a sectional view showing the structure of the vertical MOSFET with a high withstand voltage according to the prior art. FIG. 6 shows the structure of a pair of transistors.

As shown in FIG. 6, in the vertical MOSFET with a high withstand voltage according to the prior art, an N-type drain layer 31 is formed on an N-type semiconductor substrate 30 by an epitaxial method and a P-type well layer 32 having a channel region formed thereon is formed in contact with the drain layer 31 on a surface of the N-type semiconductor substrate 30. On a surface of the well layer 32 on the N-type semiconductor substrate 30, an N-type source layer 33 having a depth d of about 0.3 μm is selectively formed. Formed on the well layer 32 are trenches 35 reaching the drain layer 31. The inner surfaces of the trenches 35 are covered with gate insulating films 34 together with a region adjacent to one side of the source layer 33, and gate electrodes 36 are formed in the trenches 35. Further, a recessed structure 37 is formed on the well layer 32 which serves as a region between the adjacent source layers 33 and is adjacent to the other side of the source layer 33, and a body contact electrode 38 is formed on the inner surface of the recessed structure 37. Moreover, insulating films 39 are stacked over the gate electrodes 36. Further, a source electrode 40 is formed on the source layer 33, the body contact electrode 38, and the insulating films 39, a voltage is applied to the source layer 33, and the same voltage as the source layer 33 is applied to the body contact electrode 38. On the underside of the semiconductor substrate 30, a drain electrode 41 is formed.

In this configuration, by applying a bias voltage to the gate electrodes 36, continuity is provided between the source layer 33 and the drain layer 31. At this point, a source voltage is applied also to the body contact electrode 38, so that the potential of the well layer 32 serving as the channel region is stabilized and a breakdown voltage is improved.

### DISCLOSURE OF THE INVENTION

In the configuration of the vertical MOSFET with a high withstand voltage according to the prior art, however, the insulating film 39 is protruded in a dome shape out of the recessed structure of the trench 35 to the top surface of the source layer 33 with a height h of about 0.5 μm, in order to stack the insulating film 39 with a sufficient thickness on the gate electrodes 36. Therefore, it is necessary to increase the width of the source layer 33 to secure the connection area of the source layer 33 and the source electrode 40, which is an obstacle to size reduction.

Further, when a P-type impurity is applied into the source layer 33, the connection resistance of the source layer 33 and the source electrode 40 is increased. Thus at the formation of the P-type body contact electrode 38, it is necessary to form a mask on the source layer 33, thereby disadvantageously increasing the number of manufacturing steps.

Moreover, in order to further improve the breakdown voltage, a region for stabilizing the potential of the well layer 32 is increased by deeply forming the recessed structure 37, so that the body contact electrode 38 has to be formed at a deep position of the well layer 32. By deeply forming the recessed structure 37, a height difference between the top position of the insulating film 39 and the surface of the body contact electrode 38 is increased and the surface of the source electrode 40 becomes uneven, so that a faulty connection may disadvantageously occur on wires and the like connected to the source electrode. Further, the breakdown voltage can be improved also by forming a high-concentration impurity region on the well layer 32 to reduce a parasitic resistance, instead of deeply forming the recessed structure 37. However, the number of steps is disadvantageously increased by the formation of a mask on the source layer 33 and ion implantation for deeply forming the high-concentration impurity region.

In order to solve the problems of the prior art, an object of a semiconductor device and a method of manufacturing the same according to the present invention is to easily improve a breakdown voltage while reducing the size of the semiconductor device with fabrication accuracy.

In order to attain the object, a semiconductor device of the present invention includes: a semiconductor substrate; a well layer formed on a surface of the semiconductor substrate; a drain layer formed immediately under the well layer; trenches formed at least in the well layer with gate insulating films formed on the inner surfaces of the trenches; gate electrodes formed in the trenches; a source layer formed in contact with the trenches on a surface of the well layer; a recessed structure formed in the surface region of the well layer so as to be opposed to the trench with the source layer disposed between the trench and the recessed structure; a body contact electrode formed on the inner surface of the recessed structure; insulating films formed in the trenches to cover the gate electrodes; a source electrode formed over a surface including the source layer and the body contact electrode; and a drain electrode formed on the underside of the semiconductor substrate, wherein the source layer is so high that the source layer can be electrically connected to the source electrode only by the sides of the source layer, the recessed structure has a bottom face formed deeper than the underside of the source layer, and a depth from the top surface of the source layer to the deepest portion of the recessed structure is not larger than 1.5 times the maximum value of the width of the recessed structure.

Further, the depth from the top surface of the source layer to the deepest portion of the recessed structure is at least 1.0 times the maximum value of the width of the recessed structure.

Moreover, a semiconductor device of the present invention includes: a semiconductor substrate; a well layer formed on a surface of the semiconductor substrate; a drain layer formed immediately under the well layer; trenches formed at least in the well layer with gate insulating films formed on the inner surfaces of the trenches; gate electrodes formed in the trenches; a source layer formed in contact with the trenches on a surface of the well layer; a recessed structure formed in the surface region of the well layer so as to be opposed to the trench with the source layer disposed between the trench and the recessed structure; a body contact electrode formed on the inner surface of the recessed structure; insulating films formed in the trenches to cover the gate electrodes; a source electrode formed over a surface including the source layer and the body contact electrode; and a drain electrode formed on the underside of the semiconductor substrate, wherein the source layer is so high that the source layer can be electrically connected to the source electrode only by the sides of the source layer, the recessed structure has a convex portion formed around the center of the bottom plane of the recessed structure, and the recessed structure has the deepest position formed deeper than the underside of the source layer.

Further, a semiconductor device of the present invention includes: a semiconductor substrate; a well layer formed on a surface of the semiconductor substrate; a drain layer formed immediately under the well layer; trenches formed at least in the well layer with gate insulating films formed on the inner surfaces of the trenches; gate electrodes formed in the trenches; a source layer formed in contact with the trenches on a surface of the well layer; a body contact electrode formed in the surface region of the well layer so as to be opposed to the trench with the source layer disposed between the trench and the body contact electrode; insulating films formed in the trenches to cover the gate electrodes; a source electrode formed over a surface including the source layer and the body contact electrode; and a drain electrode formed on the underside of the semiconductor substrate, wherein the source layer is so high that the source layer can be electrically connected to the source electrode only by the sides of the source layer, and the body contact electrode has a bottom face formed deeper than the underside of the source layer.

Moreover, the body contact electrode has the deepest position between the top surface of the gate electrode and a position at a half to one third of the height of the gate electrode.

Further, the gate insulating film has a top surface lower than the top surface of the source layer.

The semiconductor device further includes an epitaxial layer formed under the drain layer with opposite conductivity from the drain layer, and a semiconductor substrate formed under the epitaxial layer with opposite conductivity from the drain layer.

A method of manufacturing a semiconductor device according to the present invention is a method of manufacturing the foregoing semiconductor device, wherein in the fabrication of the body contact electrode, an impurity is implanted in a state in which the source layer has an exposed surface.

According to the present invention, it is possible to easily improve a breakdown voltage while reducing the size of the semiconductor device with fabrication accuracy.

### BRIEF DESCRIPTION OF THE DRAWINGS

FIG. 1A is a sectional view showing the structure of a vertical MOSFET with a high withstand voltage according to a first embodiment;

FIG. 1B is a sectional view showing the structure of the vertical MOSFET with a high withstand voltage according to the first embodiment;

FIG. 2A is a process sectional view for explaining a method of manufacturing the semiconductor device according to the first embodiment;

FIG. 2B is a process sectional view for explaining the method of manufacturing the semiconductor device according to the first embodiment;

FIG. 2C is a process sectional view for explaining the method of manufacturing the semiconductor device according to the first embodiment;

FIG. 2D is a process sectional view for explaining the method of manufacturing the semiconductor device according to the first embodiment;

FIG. 3A is a process sectional view for explaining the method of manufacturing the semiconductor device according to the first embodiment;

FIG. 3B is a process sectional view for explaining the method of manufacturing the semiconductor device according to the first embodiment;

FIG. 3C is a process sectional view for explaining the method of manufacturing the semiconductor device according to the first embodiment;

FIG. 3D is a process sectional view for explaining the method of manufacturing the semiconductor device according to the first embodiment;

FIG. 4A is a process sectional view for explaining the method of manufacturing the semiconductor device according to the first embodiment;

FIG. 4B is a process sectional view for explaining the method of manufacturing the semiconductor device according to the first embodiment;

FIG. 4C is a process sectional view for explaining the method of manufacturing the semiconductor device according to the first embodiment;

FIG. 5 is a sectional view showing the structure of a vertical MOSFET with a high withstand voltage according to a second embodiment; and

FIG. 6 is a sectional view showing the structure of a vertical MOSFET with a high withstand voltage according to the prior art.

### DESCRIPTION OF THE EMBODIMENTS

### First Embodiment

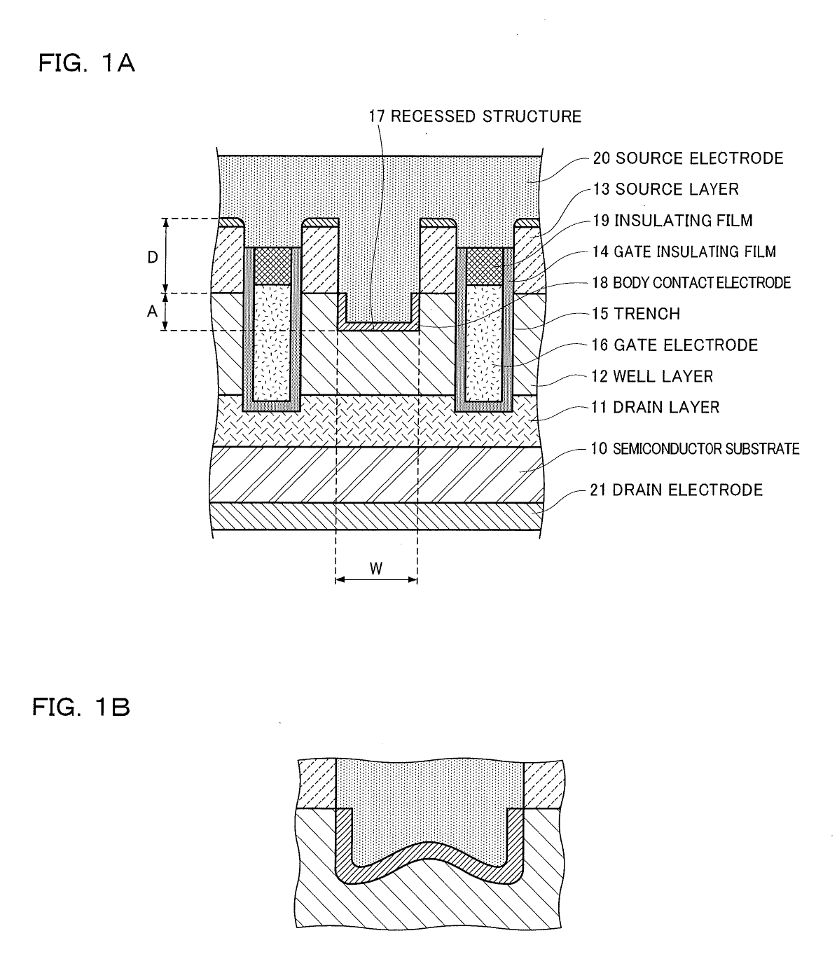

Referring to FIGS. 1A and 1B, a semiconductor device according to a first embodiment will be first described below.

FIGS. 1A and 1B are sectional views showing the structure of a vertical MOSFET with a high withstand voltage according to the first embodiment. FIG. 1A is a sectional view showing the overall structure and FIG. 1B is an enlarged view showing an example of a recessed structure.

As shown in FIG. 1A, in the vertical MOSFET with a high withstand voltage according to the first embodiment, an N-type drain layer 11 is formed on an N-type semiconductor substrate 10 by an epitaxial method and so on. On a surface of the N-type semiconductor substrate 10, a P-type well layer 12 having a channel region formed thereon is formed in contact with the drain layer 11. On a surface of the well layer 12 on the N-type semiconductor substrate 10, an N-type source layer 13 is selectively formed. Formed on the well layer 12 are trenches 15 reaching the drain layer 11. The inner surfaces of the trenches 15 are covered with gate insulating films 14 together with a region adjacent to one side of the source layer 13, and gate electrodes 16 are formed in the trenches 15. Further, a recessed structure 17 is formed on the well layer 12 which serves as a region between the adjacent source layers 13 and is adjacent to the other side of the source layer 13, and a body contact electrode 18 is formed on the inner surface of the recessed structure 17. Moreover, insulating films 19 are stacked in the trenches 15 so as to cover the gate electrodes 16. Further, a source electrode 20 is formed on the exposed source layer 13, gate insulating films 14, body contact electrode 18, and insulating films 19, a potential is applied to the source layer 13, and the same potential is applied to the body contact electrode 18. On the underside of the semiconductor substrate 10, a drain electrode 21 is formed.

In this configuration, by applying a bias voltage to the gate electrodes 16, continuity is provided between the source layer 13 and the drain layer 11. At this point, since a source voltage is applied also to the body contact electrode 18, a parasitic resistance caused by a potential difference in the well layer 12 is reduced and the charge of the well layer 12 serving as the channel region is stabilized. Thus a breakdown voltage can be improved.

In this configuration, the source layer 13 is taller than the source layer of the prior art in cross section. The source layer 13 is formed with, for example, a height D=about 0.5 μm in order to obtain, only by the sides of the source layer 13, a connection area with the source electrode 20 with a sufficiently low connection resistance. Although FIG. 1A illustrates the gate insulating films 14 formed as high as the top surface of the source layer 13, a connection area with the source electrode 20 may be obtained above the trenches 15 by forming the gate insulating films 14 with heights between the top surface of the source layer 13 and the top surfaces of the gate electrodes 16. Since the connection to the source electrode 20 is obtained thus only by the sides of the source layer 13, it is possible to reduce the area of the top surface of the source layer 13. Thus the size of the vertical MOSFET can be reduced.

Further, by increasing the height of the source layer 13, the body contact electrode 18 is formed deeper than in the prior art, thereby further improving the breakdown voltage. In other words, in the prior art, the recessed structure cannot be so deeply formed because flatness has to be secured on the surface of the source electrode 20, whereas in the present embodiment, the insulating films 19 can be sufficiently provided in the trenches 15 and the insulating films are not formed on the source layer 13, so that the recessed structure 17 can be formed more deeply than in the vertical MOSFET with a high withstand voltage according to the prior art. For example, in the vertical MOSFET with a high withstand voltage according to the prior art, the height h of the dome shape of the insulating film is 0.5 μm and a height d of the source layer is 0.3 μm, so that the recessed structure has a depth X of only 0.1 μm, whereas in the present embodiment, since the insulating films 19 are not formed on the source layer 13, even when the insulating film 19 has a depth D of 0.5 μm, the recessed structure 17 can be formed with the deepest portion having a depth A of about 0.3+0.5+0.1−0.5=0.4 μm. At this point, the width of the recessed structure 17 has a maximum value W of 0.6 and a depth from the surface of the source layer 13 to the deepest portion of the recessed structure 17 is 1.5 times the maximum value of the width of the recessed structure 17. When the depth from the surface of the source layer 13 to the deepest portion of the recessed structure 17 is larger than the maximum value of the width of the recessed structure 17, the source layer 13 has an uneven surface. For this reason, the depth from the surface of the source layer 13 to the deepest portion of the recessed structure 17 has to be 1.5 times or smaller than the maximum value of the width of the recessed structure 17. Moreover, it is necessary to increase the depth of the recessed structure 17 to increase the breakdown voltage. In reality, the depth from the surface of the source layer 13 to the deepest portion of the recessed structure 17 is preferably 1 to 1.5 times the maximum value of the width of the recessed structure 17. In this case, the deepest portion of the recessed structure 17 is formed as deeply as possible such that the deepest portion is located deeper than the underside of the source layer 13 and near the underside of the gate electrode 16, thereby achieving the effect of improving the breakdown voltage. However, in order to prevent an impurity implanted at the formation of the body contact electrode 18 from being implanted to the drain layer 11, the deepest portion is preferably formed between the top surface of the gate electrode 16 and a depth of about a half to one third of the height of the gate electrode 16.

In the foregoing explanation, the bottom face of the recessed structure 17 is substantially in parallel with the surface of the semiconductor substrate 10. As shown in FIG. 1B, a convex structure may be provided around the center of the bottom flat shape of the recessed structure 17. With the convex structure, the formation of an uneven surface on the source electrode 20 is suppressed even when the deepest portion of the recessed structure 17 is more deeply formed. Thus it is possible to form the recessed structure 17 with the deepest portion more deeply located, as far as an impurity can be prevented from being implanted into the drain layer 11.

As previously mentioned, the height of the source layer 13 is increased and the sufficient connection to the source electrode 20 is secured only by the sides of the source layer 13, so that the area of the top surface of the source layer 13 can be minimized. Thus the size of the vertical MOSFET can be reduced. Further, the height of the source layer 13 is increased and the insulating films 19 on the gate electrodes 16 are formed only in the trenches 15 without protruding onto the source layer 13, so that the body contact electrode 18 can be deeply formed while keeping flatness on the surface of the source electrode 20. Thus it is possible to improve the breakdown voltage while securing the accuracy of bonding to the source electrode 20.

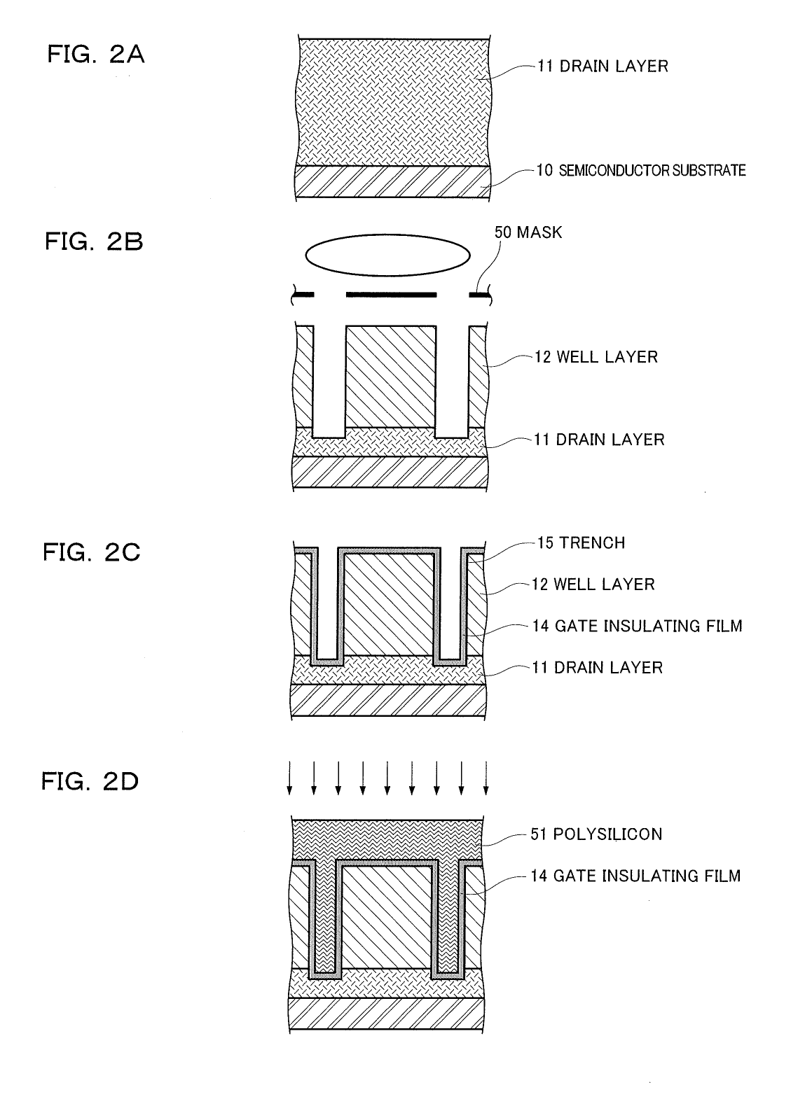

Referring to FIGS. 2 to 4, the following will describe a method of manufacturing the semiconductor device according to the first embodiment.

FIGS. 2A, 2B, 2C, 2D, 3A, 3B, 3C, 3D, 4A, 4B, and 4C are process sectional views for explaining the method of manufacturing the semiconductor device according to the first embodiment.

First, the drain layer 11 is grown on the N-type semiconductor substrate 10 by an epitaxial growth method (FIG. 2A).

Next, the P-type well layer 12 is formed on the surface of the semiconductor substrate 10 by implanting impurity ions over the drain layer 11. After that, the well layer 12 is selectively etched using a mask 50 for opening the formation regions of the trenches 15. At this point, the upper part of the drain layer 11 is also partially etched such that the drain layer 11 has a convex shape (FIG. 2B).

Next, an oxide film acting as the gate insulating film 14 is formed over the surface of the semiconductor substrate 10 by an oxide film growth method, so that the trenches 15 are formed (FIG. 2C).

After that, polysilicon 51 is grown over the oxide film and N-type high-concentration ions are implanted to reduce a resistance (FIG. 2D).

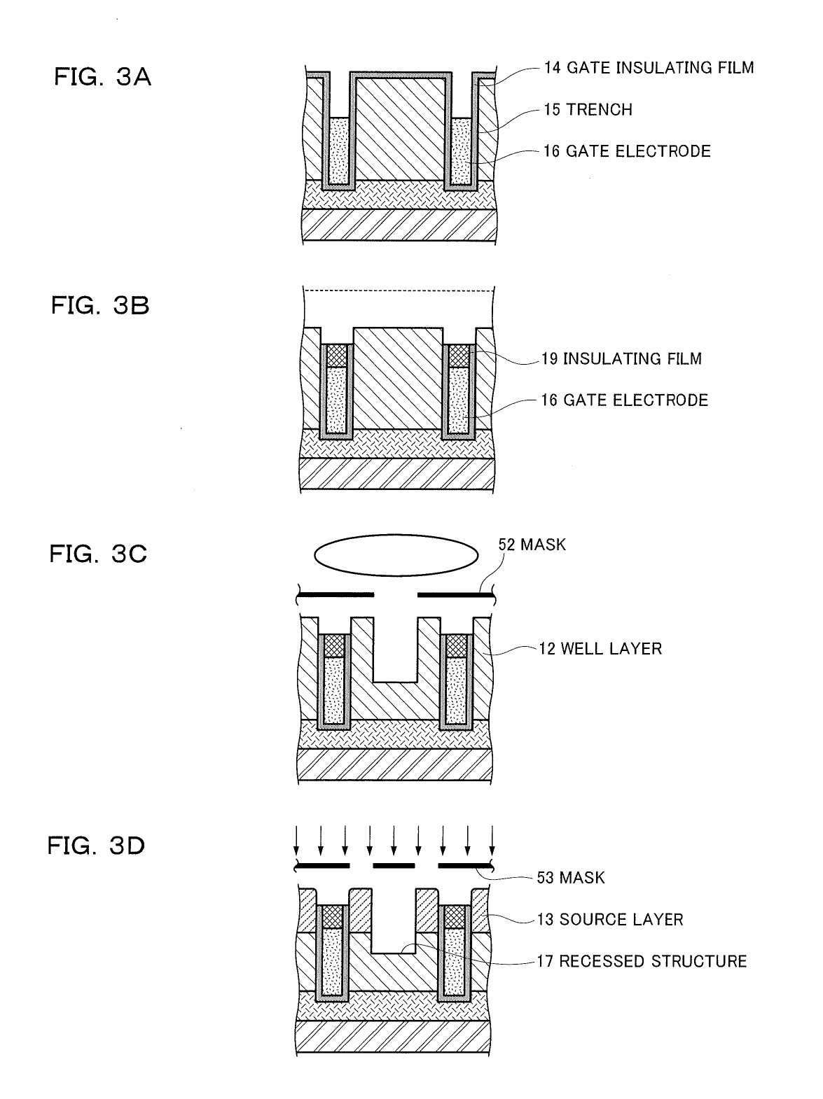

Next, the polysilicon 51 is partially removed by etching, so that the gate electrodes 16 with a predetermined height are formed in the trenches 15 (FIG. 3A).

After that, an interlayer insulating film is stacked over the surface. The interlayer insulating film on the gate electrodes 16 is left as the insulating films 19 and the interlayer insulating film on other portions is removed by etching. At this point, the oxide film on the well layer 12 is removed at the same time. Further, the oxide film on the sides of the well layer 12 may be partially removed (FIG. 3B).

Next, a part of the surface of the well layer 12 is selectively plasma etched using a mask 52 (FIG. 3C).

Moreover, ions are implanted into the upper part of the remaining well layer 12 by using a mask 53, so that the N-type source layer 13 is formed. Thus the etching region of the well layer 12 deeper than the source layer 13 acts as the recessed structure 17 (FIG. 3D).

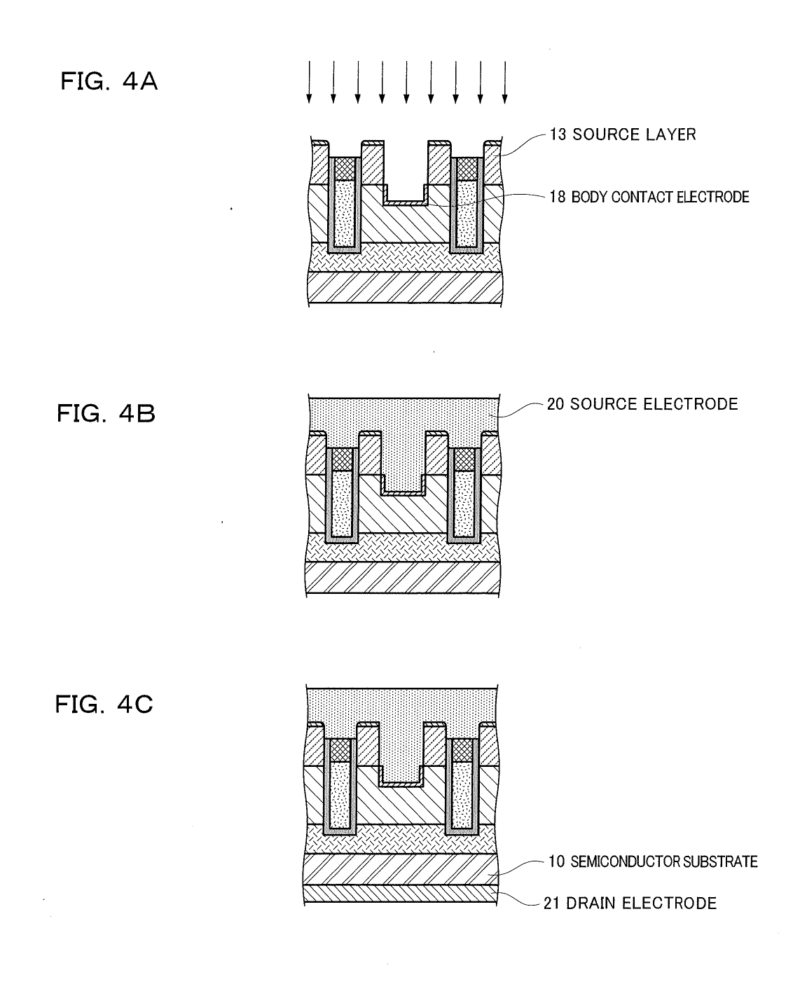

Next, P-type ions are implanted over the surface to form the body contact electrode 18 on the surface of the recessed structure 17. At this point, when the ions are implanted without using a mask, the ions are also implanted into the source layer 13 and the surface of the source layer 13 has a high resistance. The connection to the electrode is made only by the sides of the source layer 13 and thus the high resistance on the surface of the source layer 13 does not cause any problems. The body contact electrode 18 can be formed without using a mask and thus can be formed by a simple manufacturing process (FIG. 4A).

Next, aluminum sputtering is performed over the surface, so that the source electrode 20 is formed with electrical connection to both the sides of the source layer 13 and the body contact electrode 18 (FIG. 4B).

Finally, the drain electrode 21 is formed on the underside of the semiconductor substrate 10, so that the semiconductor device of FIG. 1 is completed (FIG. 4C).

### Second Embodiment

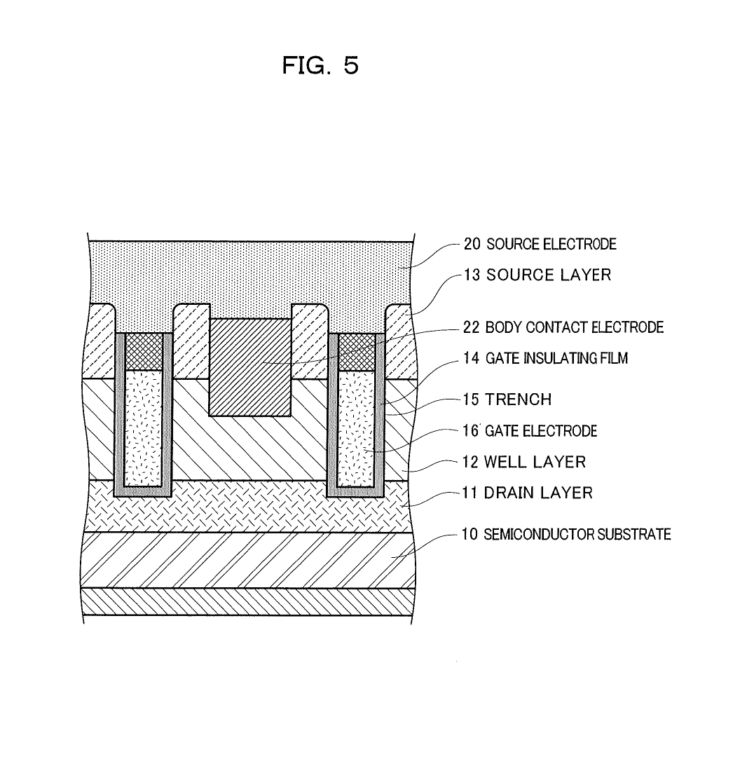

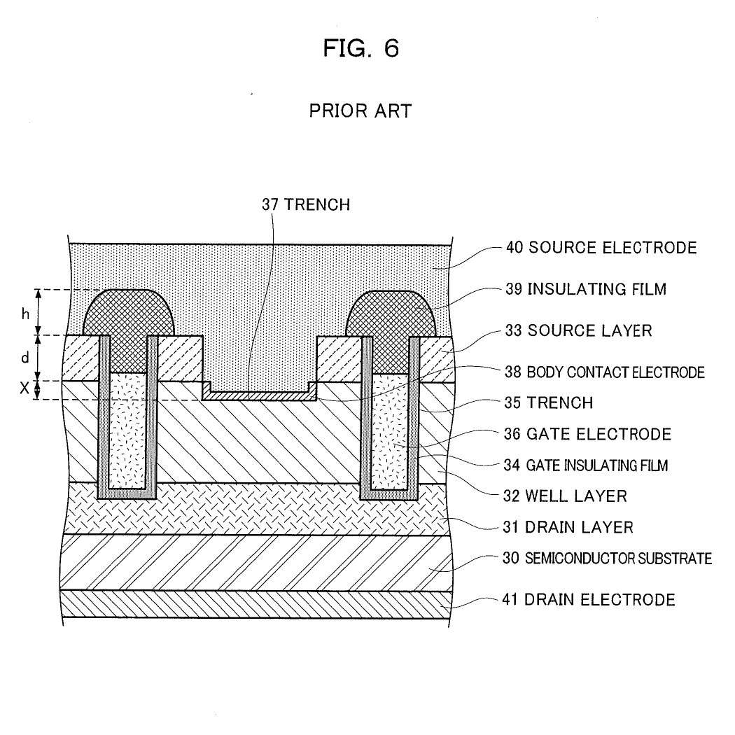

Referring to FIG. 5, the following will describe a semiconductor device and a method of manufacturing the same according to a second embodiment.

FIG. 5 is a sectional view showing the structure of a vertical MOSFET with a high withstand voltage according to the second embodiment. The same configurations as in FIG. 1 will be indicated by the same reference numerals and the explanation thereof is omitted.

In FIG. 5, a recessed structure 17 (see FIG. 1) is not formed and a body contact electrode 22 is formed only by implanting an impurity. Like the recessed structure 17 (see FIG. 1) of the first embodiment, the body contact electrode 22 is formed as deeply as possible such that the body contact electrode 22 is deeper than the underside of a source layer 13 and close to the underside of a gate electrode 16. Preferably, the body contact electrode 22 is formed between the top surface of the gate electrode 16 and a depth of about a half to one third of the height of the gate electrode 16 in consideration of the impurity implanted into a drain layer 11. Further, gate insulating films 14 in trenches 15 are formed so as to be lower than a surface of a semiconductor substrate 10, and the sides of the source layer 13 are exposed with steps formed between the source layer 13 and the body contact electrode 22 due to the implantation of the impurity at the formation of the body contact electrode 22 and steps formed between the source layer 13 and the gate insulating film 14. Thus the gate insulating films 14 are formed so as to sufficiently secure connection to a source electrode 20 only by the exposed sides of the source layer 13.

As previously mentioned, the height of the source layer 13 is increased and the sufficient connection to the source electrode 20 is secured only by the sides of the source layer 13, so that the area of the top surface of the source layer 13 can be minimized. Thus size reduction can be achieved for the vertical MOSFET. Further, the body contact electrode 22 is deeply formed only by implanting the impurity without forming the recessed structure 17 (see FIG. 1) on the well layer 12, so that a body contact electrode 18 can be deeply formed while keeping flatness on the surface of the source electrode 20. Thus it is possible to improve a breakdown voltage while securing the accuracy of bonding to the source electrode 20. Since the connection to the source electrode is made only by the sides of the source layer 13, the implantation of an impurity at this point does not require a mask, thereby suppressing an increase in the number of manufacturing steps.

The vertical MOSFETs with a high withstand voltage according to the foregoing embodiments are sequentially formed in pairs, and the gate electrode wires, source electrode wires, and drain electrode wires of the vertical MOSFETs are connected in common, so that a switching device can be formed for a power supply and the like.

In this case, the trenches in which the gate electrodes are formed are preferably formed in parallel because stable characteristics are obtained.

In the foregoing embodiments, the N-channel vertical transistors are formed on the N-type semiconductor substrates. P-channel vertical transistors can be also formed in a similar configuration. Further, insulated-gate bipolar transistors (IGBTs) can be also formed in a similar configuration.

What is claimed is:

1. A semiconductor device comprising:
a semiconductor substrate;
a well layer formed on a surface of the semiconductor substrate;
a drain layer formed in contact with an underside of the well layer;
trenches formed at least in the well layer with gate insulating films formed on inner surfaces of the trenches;
gate electrodes formed in the trenches;
a source layer formed in contact with the trenches on a surface of the well layer;
a recessed structure formed in a surface region of the well layer so as to be opposed to the trench with the source layer disposed between the trench and the recessed structure;
a body contact electrode formed on an inner surface of the recessed structure;
insulating films formed in the trenches to cover the gate electrodes;
a source electrode formed over a surface including the source layer and the body contact electrode; and
a drain electrode formed on an underside of the semiconductor substrate,
wherein the source layer is so high that the source layer can be electrically connected to the source electrode only by sides of the source layer, the recessed structure has a bottom face formed deeper than an underside of the source layer, and a depth from a top surface of the source layer to a deepest portion of the recessed structure is not larger than 1.5 times a maximum value of a width of the recessed structure.

2. The semiconductor device according to claim 1, wherein the depth from the top surface of the source layer to the deepest portion of the recessed structure is at least 1.0 times the maximum value of the width of the recessed structure.

3. The semiconductor device according to claim 1, wherein the recessed structure has a convex portion formed around a center of a bottom plane of the recessed structure, and the recessed structure has a deepest position formed deeper than the underside of the source layer.

4. A semiconductor device comprising:
a semiconductor substrate;
a well layer formed on a surface of the semiconductor substrate;
a drain layer formed in contact with an underside of the well layer;
trenches formed at least in the well layer with gate insulating films formed on inner surfaces of the trenches;
gate electrodes formed in the trenches;
a source layer formed in contact with the trenches on a surface of the well layer;
a body contact electrode formed in a surface region of the well layer so as to be opposed to the trench with the source layer disposed between the trench and the body contact electrode;
insulating films formed in the trenches to cover the gate electrodes;
a source electrode formed over a surface including the source layer and the body contact electrode; and
a drain electrode formed on an underside of the semiconductor substrate,
wherein the source layer is so high that the source layer can be electrically connected to the source electrode only by sides of the source layer, and the body contact electrode has a bottom face formed deeper than an underside of the source layer.

5. The semiconductor device according to claim 1, wherein the body contact electrode has a deepest position between a top surface of the gate electrode and a position at a half to one third of a height of the gate electrode.

6. The semiconductor device according to claim 1, wherein the gate insulating film has a top surface lower than the top surface of the source layer.

7. The semiconductor device according to claim 1, further comprising an epitaxial layer formed under the drain layer with opposite conductivity from the drain layer, and a semiconductor substrate formed under the epitaxial layer with opposite conductivity from the drain layer.

8. A method of manufacturing the semiconductor device according to claim 1, wherein in fabrication of the body contact electrode,
an impurity is implanted in a state in which the source layer has an exposed surface.
